(19) United States
(12) Patent Application Publication
(10) Pub. No.: US 2026/0096303 A1
(43) Pub. Date: Apr. 2, 2026

(54) DISPLAY PANEL, MANUFACTURING METHOD OF THE SAME, AND DISPLAY DEVICE

(71) Applicant: HKC CORPORATION LIMITED, SHENZHEN (CN)

(72) Inventors: Yao LI, SHENZHEN (CN); Pei XU, SHENZHEN (CN)

(73) Assignee: HKC CORPORATION LIMITED, SHENZHEN (CN)

(21) Appl. No.: 19/321,239

(22) Filed: Sep. 7, 2025

(30) Foreign Application Priority Data
Sep. 30, 2024 (CN) 202411393340.5

(51) Int. Cl. H10K 59/123; H10K 59/12; H10K 59/131

(52) U.S. Cl. CPC H10K 59/123; H10K 59/1201; H10K 59/131

(57) ABSTRACT

A display panel, a manufacturing method of the same, and a display device. The display panel includes a drive substrate and a light-emitting substrate. The drive substrate includes a drive circuit layer and multiple drive electrodes that are electrically connected to the drive circuit layer. The light-emitting substrate includes: a glass substrate, where the glass substrate defines glass through holes, each of which is filled with a conductive portion, and the conductive portion is electrically connected to a corresponding drive electrode; and multiple light-emitting units, where an anode of each light-emitting unit is electrically connected to a corresponding conductive portion. A second side of the glass substrate close to the drive substrate defines a ring-shaped groove that surrounds the multiple glass through holes; a barrier layer is disposed within the ring-shaped groove to absorb water and oxygen and prevent the water and oxygen from entering the multiple glass through holes.

### CROSS-REFERENCE TO RELATED APPLICATIONS

The present application claims priority of Chinese Patent Application No. 202411393340.5, filed on Sep. 30, 2024, the entire contents of which are hereby incorporated by reference in their entirety.

### TECHNICAL FIELD

The present disclosure relates to the field of display technologies, and in particular to a display panel, a manufacturing method of the same, and a display device.

### BACKGROUND

A single-crystal silicon drive backplate is a drive substrate formed by semiconductor devices fabricated through Complementary Metal Oxide Semiconductor (CMOS) processes as driving units. Compared to conventional Active-matrix organic light-emitting diode (AMOLED) panels that utilize amorphous silicon, microcrystalline silicon, or low-temperature polycrystalline silicon thin-film transistors as backplates, the single-crystal silicon drive backplate demonstrates significantly higher carrier mobility. Consequently, Silicon-based Organic Light-Emitting Diode (SiOLED) display panels are currently the highest-performance display technology applied in AR/VR products.

Currently, the silicon-based OLED display panel integrates the conventional externally-bonded display chip into the silicon-based drive backplate. The fabrication method thereof involves vapor-depositing OLED light-emitting devices onto a silicon-based drive substrate. Specifically, this process includes: depositing to form an anode; forming a pixel definition layer; and sequentially, depositing an organic emissive layer and a cathode. This approach enables the production of subpixels with smaller dimensions, thereby achieving display fineness exceeding retinal resolution, further with advantages such as high resolution, high integration density, low power consumption, compact size, and lightweight structure.

However, directly vapor-depositing OLED emissive devices onto the silicon-based drive substrate may easily affect the silicon-based drive circuits, causing damage to the drive circuits and rendering them unusable, thereby increasing costs.

### SUMMARY OF THE DISCLOSURE

The present disclosure provides a display panel, including:
a drive substrate, including a drive circuit layer and a plurality of drive electrodes that are electrically connected to the drive circuit layer; and
a light-emitting substrate, including:
   a glass substrate, disposed on the drive substrate; wherein the glass substrate defines a plurality of glass through holes on a second side of the glass substrate corresponding to and facing the plurality of drive electrodes; the second side is opposite to the first side; each of the plurality of glass through holes is filled with a conductive portion, and the conductive portion is electrically connected to a corresponding drive electrode; and
   a plurality of light-emitting units, arranged in an array on a first side of the glass substrate; wherein an anode of each of the plurality of light-emitting units is electrically connected to a corresponding conductive portion;
wherein the second side of the glass substrate close to the drive substrate defines a ring-shaped groove that surrounds the plurality of glass through holes; a barrier layer is disposed within the ring-shaped groove to absorb water and oxygen and prevent the water and oxygen from entering the plurality of glass through holes.

The present disclosure further provides a manufacturing method of the display panel as above.

The present disclosure further provides a display device, including:
the display panel as above; and
a control circuit board, electrically connected to the display panel and configured to control the display panel.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a display panel according to some embodiments of the present disclosure.

FIG. 2 is a longitudinal cross-sectional structural schematic view of an anode through hole and a first isolation groove according to some embodiments of the present disclosure.

FIG. 3 is a top structural schematic view of an anode through hole and a first isolation groove according to some embodiments of the present disclosure.

FIG. 4 is a top structural schematic view of a cathode through hole and a second isolation groove according to some embodiments of the present disclosure.

FIG. 5 is a longitudinal cross-sectional structural schematic view of a cathode through hole and a second isolation groove according to some embodiments of the present disclosure.

FIG. 6 is a top structural schematic view of a cathode through hole and a second isolation groove according to other embodiments of the present disclosure.

FIG. 7 is a longitudinal cross-sectional structural schematic view of a dam region according to some embodiments of the present disclosure.

FIG. 8 is a top structural schematic view of an isolation through hole according to some embodiments of the present disclosure.

FIG. 9 is a top structural schematic view of an isolation through hole according to other embodiments of the present disclosure.

FIG. 10 is a flowchart of a method for manufacturing a display panel according to some embodiments of the present disclosure.

FIG. 11 is a flowchart of a method for manufacturing a display panel according to other embodiments of the present disclosure.

FIG. 12 is a structural schematic view of a display device according to some embodiments of the present disclosure.

### DETAILED DESCRIPTION

The following description, in conjunction with the accompanying drawings, provides a detailed explanation of the technical solutions of the embodiments of the present disclosure.

In the following description, specific details such as specific system structures, interfaces, and technologies are provided for the purpose of explanation rather than limitation, in order to facilitate a thorough understanding of the present disclosure.

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first,” “second,” and “third” used in the present disclosure are for descriptive purposes only and should not be understood as indicating or implying relative importance or the number of technical features indicated. Therefore, features defined with “first,” “second,” or “third” may explicitly or implicitly include at least one of the features indicated. In the description of the present disclosure, “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have,” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

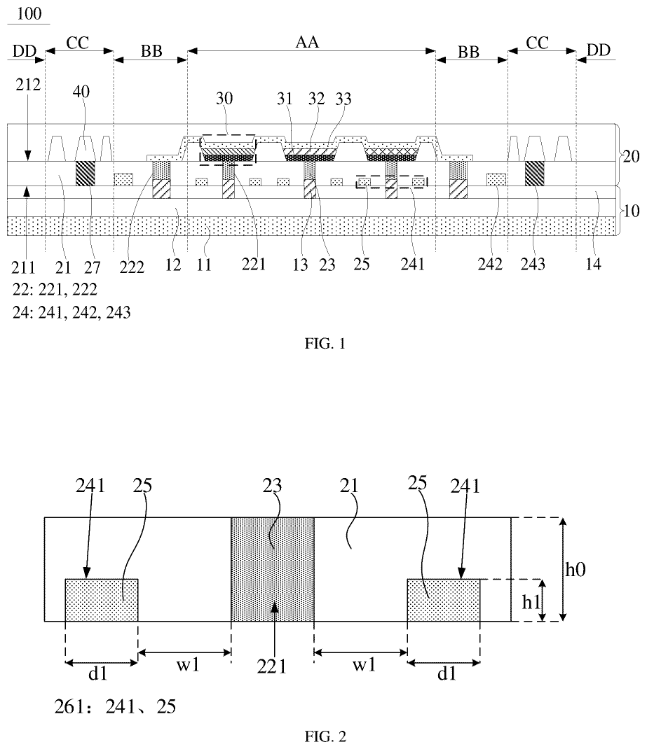

Referring to FIG. 1, FIG. 1 is a structural schematic view of a display panel according to some embodiments of the present disclosure. In the embodiments, a display panel 100 is provided, which includes a drive substrate 10 and a light-emitting substrate 20. The drive substrate 10 is aligned with and electrically connected to the light-emitting substrate 20 to drive the light-emitting substrate 20 to display an image.

The drive substrate 10 includes a drive circuit layer 12 and multiple drive electrodes 13. The drive circuit layer 12 includes multiple pixel drive circuits (not shown), each of which includes a semiconductor drive device. In some embodiments, CMOS device may be used as the semiconductor drive devices to form the pixel drive circuits, thereby driving the light-emitting substrate 20 to emit light. The multiple drive electrodes 13 are each electrically connected to a corresponding pixel drive circuit and a corresponding pixel power supply signal to transmit a corresponding drive signal to the light-emitting substrate 20.

In some embodiments, the drive substrate 10 may further include a silicon-based substrate 11 and an insulating protective layer 14. The silicon-based substrate 11 is configured to support the drive circuit layer 12 and the drive electrodes 13. In some embodiments, the silicon-based substrate 11 may be configured as a single-crystal silicon substrate. The insulating protective layer 14 is disposed on a side of the drive circuit layer 12 away from the silicon-based substrate 11 and defines multiple openings, which are disposed in correspondence with and facing the drive electrodes 13, for exposing the drive electrodes 13.

The light-emitting substrate 20 includes a glass substrate 21 and light-emitting units 30 disposed on a first side 211 of the glass substrate 21 away from the drive substrate 10. The glass substrate 21 is disposed on the drive substrate 10, and the glass substrate 21 defines multiple glass through holes 22 corresponding to the drive electrodes 13. Each glass through hole 22 is filled with a conductive portion 23, which is electrically connected to a corresponding drive electrode 13 of the drive substrate 10. The light-emitting units 30 are arranged in an array on the first side 211 of the glass substrate 21, and an anode 31 of each light-emitting unit 30 is electrically connected to a corresponding conductive portion 23. In some embodiments, the glass through hole 22 may be a circular through hole or rectangular through hole, or may be a polygonal through hole, elliptical through hole, or of other hole shapes, which may be selected based on actual requirements.

Through the above configuration, the glass substrate 21 is interposed between the drive substrate 10 and the light-emitting units 30. The light-emitting units 30 are fabricated on the glass substrate 21, and the glass substrate 21 may protect the drive circuit layer 12 on the drive substrate 10, thereby preventing direct fabrication of the light-emitting substrate 20 on the drive substrate 10 from affecting or damaging the drive circuit layer 12, and thus improving product yield. By defining the glass through holes 22 on the glass substrate 21 and arranging the conductive portions 23 within the glass through holes 22, the light-emitting unit 30 can be connected to the drive substrate 10 via the conductive portions 23 to enable image display functionality.

Furthermore, by using the glass substrate 21 as a carrier substrate for the light-emitting substrate 20, compared to a silicon-based carrier substrate, the glass substrate 21 has excellent insulating properties. Therefore, there is no need to form an oxide insulating layer on the walls of the glass through holes 22, nor is specialized thin wafer handling technology required, thereby reducing costs. Additionally, due to the excellent insulating properties of the glass substrate 21, electromagnetic coupling effects are minimized during signal transmission, thereby effectively reducing signal insertion loss and crosstalk, and thus ensuring signal integrity. Furthermore, by fabricating the light-emitting units 30 on the glass substrate 21, it is advantageous for realizing a large-sized light-emitting substrate 20.

In the embodiments, the light-emitting unit 30 includes an anode 31, a light-emitting layer 32, and a cathode 33, which are stacked in sequence in a direction away from the glass substrate 21. The cathodes 33 of the light-emitting units 30 are interconnected and extend to a display edge region BB of the glass substrate 21, so as to be connected to a cathode power supply signal on the drive substrate 10 via the conductive portions 23 in the glass through holes 22, thereby ensuring that the cathode voltages of all light-emitting units 30 are the same. In some embodiments, the light-emitting units 30 may include a first light-emitting unit, a second light-emitting unit, and a third light-emitting unit with different light-emitting colors, such as a red light-emitting unit, a green light-emitting unit, and a blue light-emitting unit, to achieve color display. Specifically, the light-emitting color of the light-emitting unit 30 is determined by the light-emitting color of its light-emitting layer 32. Alternatively, in other embodiments, the light-emitting units 30 may be of the same light-emitting color, such as white, red, green, blue, etc., which may be set according to actual needs. For example, the light-emitting units 30 are white, and grayscale display is achieved by controlling the brightness of the light-emitting units 30, and a color-blocking layer may be added above the light-emitting units 30 to achieve color display. The light-emitting unit 30 may specifically be a current-driven light-emitting device, such as an organic light-emitting diode (OLED), a light-emitting diode (LED), a mini light-emitting diode (Mini-LED), or a micro light-emitting diode (Micro-LED), or a combination thereof. In the embodiments, the light-emitting unit 30 is illustrated using an OLED as an example.

In the embodiments, the glass substrate 21 is arranged between the drive substrate 10 and the light-emitting units 30, and the glass through holes 22 are defined on the glass substrate 21. The light-emitting unit 30 is connected to the drive substrate 10 below through the conductive portion 23 within the through hole, enabling the transmission of drive signals and thereby achieving image display. Since multiple glass through holes are defined on the glass substrate 21, and the glass through holes 22 are filled with the conductive portions 23, the number of potential pathways for water and oxygen to enter may be increased. When the encapsulation between the glass substrate 21 and the drive substrate 10 fails, water and oxygen may easily spread through the glass through holes 22 and enter the organic light-emitting layer 32 of the light-emitting unit 30, thereby increasing the risk of long-term reliability failure of the glass through holes 22.

To address the above technical issues, in some embodiments, a second side 212 of the glass substrate 21 close to the drive substrate 10 defines a ring-shaped groove 24, which surrounds the glass through holes 22. A barrier layer 25 is disposed within the ring-shaped groove 24 to absorb water and oxygen, preventing them from entering the glass through holes 22. That is, the ring-shaped groove is defined around the glass through holes 22 on a side of the glass substrate 21 close to the drive substrate 10, and the barrier layer 25 is arranged in the ring-shaped groove to form a ring-shaped isolation zone around the glass through holes 22. The barrier layer 25 can absorb water and oxygen that has spread to this area, preventing it from entering the glass through holes 22, thereby improving the reliability of the glass through holes 22.

Specifically, the display panel 100 includes a display region AA, a display edge region BB, and a dam region CC. The display region AA is disposed in a central main region of the display panel 100 and is configured to display images. The display edge region BB is disposed on an outer side of the display region AA and surrounds the display region AA. The display edge region BB is primarily configured for connections to signals and connections to a drive chip. The dam region CC is disposed on a side of the display edge region BB away from the display region AA and surrounds the display edge region BB. The dam region CC is arranged with an isolation dam structure to block external water and oxygen.

Corresponding to the display region AA and the display edge region BB, the glass through holes 22 on the glass substrate 21 include an anode through hole 221 disposed in the display region AA and a cathode through hole 222 disposed in the display edge region BB. The anode through holes 221 correspond to the anodes 31 of the light-emitting units 30, and the anodes 31 of the light-emitting units 30 are electrically connected to the conductive portions 23 within the anode through holes 221. The cathode through holes 222 correspond to the cathodes 33 of the light-emitting units 30, and the cathodes 33 of the light-emitting units 30 are electrically connected to the conductive portions 23 within the cathode through holes 222.

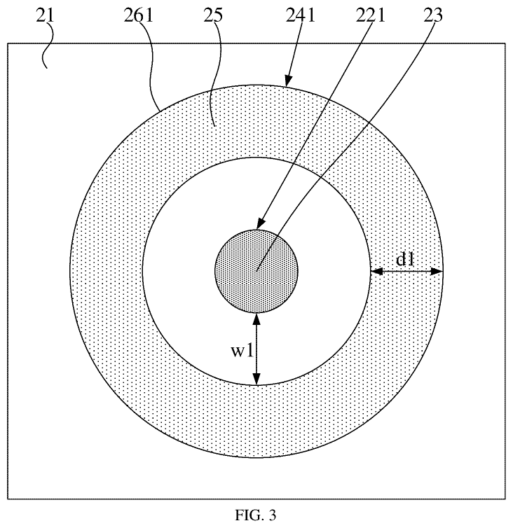

Referring to FIGS. 2 and 3, FIG. 2 is a longitudinal cross-sectional structural schematic view of an anode through hole and a first isolation groove according to some embodiments of the present disclosure, and FIG. 3 is a top structural schematic view of an anode through hole and a first isolation groove according to some embodiments of the present disclosure. In the embodiments, the ring-shaped groove 24 includes a first isolation groove 241 arranged around the anode through hole 221, and the first isolation groove 241 is filled with the barrier layer 25 to form a first barrier portion 261.

In some embodiments, the material of the barrier layer 25 may specifically be a moisture-absorbing material, such as a porous material with elastic water absorption, including elastic porous foam, silicone-based moisture-absorbing materials, porous rubber, or any combination thereof. In other embodiments, the material of the barrier layer 25 may be an organic moisture-absorbing material of the acrylic type, specifically a moisture-absorbing resin material based on polyacrylate, such as superabsorbent polymers (SAPs), crosslinked acrylic copolymers, acrylic composite materials, acrylic gels, acrylic hydrogels, or any combination thereof.

In the embodiments, the first isolation groove 241 is formed around the periphery of the anode through hole 221, and the barrier layer 25 is filled within the first isolation groove 241 to form the first barrier portion 261. When water and oxygen spreads to this area, the first barrier portion 261 can absorb the water and oxygen, thereby blocking water and oxygen and preventing them from further spreading to the anode through hole 221 and entering the light-emitting layer 32 along the anode through hole 221, which may improve the reliability of the anode through hole 221 and extend the service life of the display panel 100.

Specifically, on a surface of the glass substrate 21 close to the drive substrate 10, the first isolation groove 241 is spaced apart from the anode through hole 221 by a first preset distance w1, and the first isolation groove 241 has a first preset width d1; the first preset distance w1 is less than half a distance between adjacent anode through holes 221. In a thickness direction of the glass substrate 21, a first depth h1 of the first isolation groove 241 has a first preset ratio with respect to a reference thickness h0 of the glass substrate 21; the range of the first preset ratio is 1:3 to 1:2.

The first preset distance w1 is defined as a distance between a side of the anode through hole 221 close to the first isolation groove 241 and a side of the first isolation groove 241 close to the anode through hole 221, on a surface of the second side 212 of the glass substrate 21 along a radial direction of the anode through hole 221 or a radial direction of the first isolation groove 241. Specifically, the first isolation groove 241 may be coaxially arranged with the corresponding anode through hole 221. In some embodiments, the diameter of the anode through hole 221 is 0.5 to 1.5 μm, and the first preset distance w1 between the first isolation groove 241 and the anode through hole 221 is 1 to 2 μm, for example, 1 μm, 1.1 μm, 1.2 μm, 1.3 μm, 1.4 μm, 1.5 μm, 1.6 μm, 1.7 μm, 1.8 μm, 1.9 μm, or 2.0 μm. The specific value may be determined based on the diameter of the anode through hole 221 and the spacing between adjacent anode through holes 221, to ensure the effectiveness of the first barrier portion 261 in blocking water and oxygen even when the spacing between adjacent anodic through holes 221 is limited, thereby preventing poor water-oxygen barrier performance due to excessive proximity.

The first preset width d1 is defined as a maximum width of the first isolation groove 241 in its radial direction, along a direction parallel to the glass substrate 21. In some embodiments, the first preset width d1 may be 0.5 to 1 μm, for example, 0.5 μm, 0.6 μm, 0.7 μm, 0.8 μm, or 1.0 μm, which may be specifically set based on the spacing between adjacent anode through holes 221 and the first preset distance w1, to ensure that the spacing between adjacent first isolation grooves 241 is maintained at a safe distance, preventing the spacing from being too small or too large. If the spacing is too small, it may affect the strength of the glass substrate 21, while if the spacing is too large, it may impair the water-oxygen barrier effect.

In the thickness direction of the glass substrate 21, the first depth h1 of the first isolation groove 241 has a first preset ratio with respect to the reference thickness h0 of the glass substrate 21; the range of the first preset ratio is 1:3 to 1:2. That is, in the thickness direction of the glass substrate 21, the first depth h1 of the first isolation groove 241 is ⅓ to ½ of the reference thickness h0 of the glass substrate 21, such that the first depth h1 is sufficiently large without compromising the strength of the glass substrate 21, thereby further increasing the capacity of the first isolation groove 241 and increasing the volume of the barrier layer 25 filled therein, which enables the barrier layer 25 to absorb and store more water and oxygen, further enhancing the water absorption capacity and water-oxygen barrier effect of the first barrier portion 261.

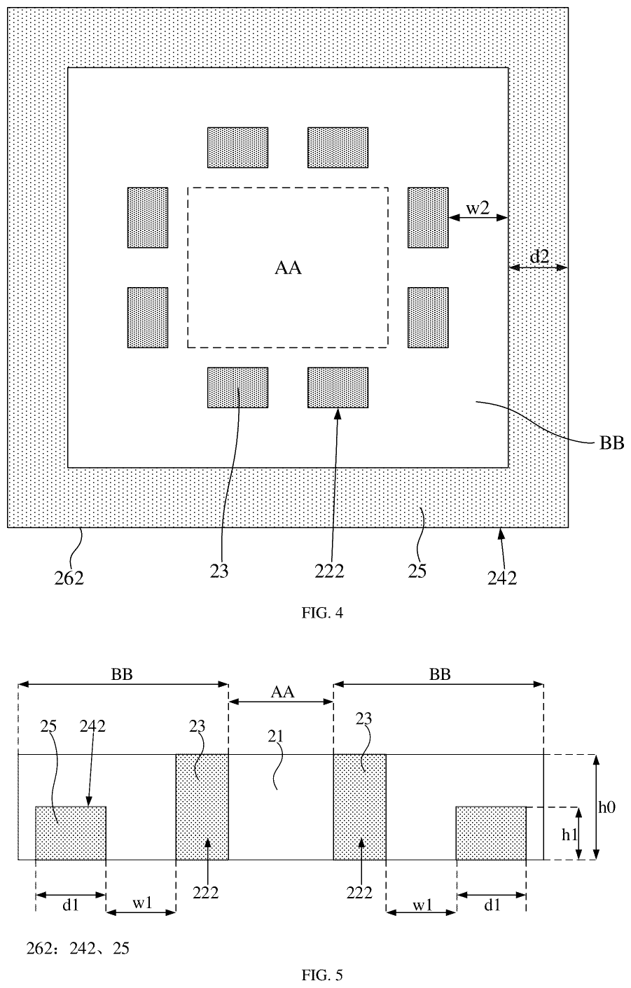

Referring to FIGS. 4 and 5, FIG. 4 is a top structural schematic view of a cathode through hole and a second isolation groove according to some embodiments of the present disclosure, and FIG. 5 is a longitudinal cross-sectional structural schematic view of a cathode through hole and a second isolation groove according to some embodiments of the present disclosure. In the embodiments, the ring-shaped groove 24 further includes a second isolation groove 242 disposed in the display edge region BB. The second isolation groove 242 is arranged around the cathode through hole 222, and the second isolation groove 242 is filled with the barrier layer 25 to form a second barrier portion 262.

Specifically, the second isolation groove 242 is a single ring-shaped groove disposed on a side of the cathode through hole 222 away from the display region AA and surrounding all the cathode through holes 222. That is, the second isolation groove 242 is a single ring-shaped groove located on a side of all the cathode through holes 222 away from the display region AA and surrounding all the cathode through holes 222.

In the embodiments, by arranging the ring-shaped second isolation groove 242 around the periphery of the cathode through holes 222 and filling the second isolation groove 242 with the barrier layer 25 to form the second barrier portion 262, the second barrier portion 262 not only surrounds the outer side of the cathode through holes 222 but also surrounds the display region AA. When water and oxygen spreads to this area, the first barrier portion 261 can absorb the water and oxygen, preventing water and oxygen from further spreading to the cathode through holes 222 and the display region AA, which may not only improve the reliability of the cathode through hole 222 but also serve as an additional barrier for the anode through holes 221, further enhancing the reliability of the anode through holes 221 and extending the service life of the display panel 100.

Specifically, on the surface of the glass substrate 21 close to the drive substrate 10, the second isolation groove 242 is spaced apart from the cathode through hole 222 by a second preset distance w2, and the second isolation groove 242 has a second preset width d2; the second preset distance w2 is greater than the first preset distance w1, and the second preset width d2 is greater than the first preset width d1. In the thickness direction of the glass substrate 21, a second depth h2 of the second isolation groove 242 has a second preset ratio relative to the reference thickness h0 of the glass substrate 21; the range of the second preset ratio is 2:5 to 3:5.

Similarly to the first preset distance w1, the second preset distance w2 is defined as a distance between a side of the cathode through hole 222 close to the second isolation groove 242 and a distance between a side of the second isolation groove 242 close to the cathode through hole 222, on the surface of the second side 212 of the glass substrate 21 along a radial direction of the second isolation groove 242. In some embodiments, the diameter of the cathode through hole 222 is 1.5 to 2.5 μm, and the second preset distance w2 between the second isolation groove 242 and the cathode through hole 222 is 2 to 5 μm, for example, 2 μm, 2.2 μm, 2.4 μm, 2.6 μm, 2.8 μm, 3.0 μm, 3.2 μm, 3.4 μm, 3.6 μm, 3.8 μm, 4.0 μm, 4.2 μm, 4.4 μm, 4.6 μm, 4.8 μm, or 5.0 μm, which may be specifically set based on the width of the display edge region BB and the second preset width d2. The area of the display edge region BB is relatively large. Compared to the first preset distance w1, the second preset distance w2 may be set relatively greater, thereby reducing the process difficulty of opening holes and slots, while ensuring the effectiveness of the second barrier portion 262 in blocking water and oxygen and preventing poor performance due to excessive proximity.

Similarly to the first preset width d1, the second preset width d2 is defined as a maximum width of the second isolation groove 242 in its radial direction, along a direction parallel to the glass substrate 21. In some embodiments, the second preset width d2 may be 2 to 5 μm, for example, 2 μm, 2.2 μm, 2.4 μm, 2.6 μm, 2.8 μm, 3.0 μm, 3.2 μm, 3.4 μm, 3.6 μm, 3.8 μm, 4.0 μm, 4.2 μm, 4.4 μm, 4.6 μm, 4.8 μm, or 5.0 μm, which may be specifically set based on the width of the display edge region BB and the second preset distance w2 to increase the capacity of the second isolation groove 242, thereby enhancing the volume of the barrier layer 25 within the second isolation groove 242 and improving the water-oxygen barrier effect.

Furthermore, in the thickness direction of the glass substrate 21, the second depth h2 of the second isolation groove 242 has a second preset ratio with respect to the reference thickness h0 of the glass substrate 21; the range of the second preset ratio is 2:5 to 3:5. That is, in the thickness direction of the glass substrate 21, the second depth h2 of the second isolation groove 242 is ⅖ to ⅗ of the reference thickness h0 of the glass substrate 21, such that the second depth h2 is sufficiently large without compromising the strength of the glass substrate 21, thereby further increasing the capacity of the second isolation groove 242 and increasing the volume of the barrier layer 25 filled therein, which enables the barrier layer 25 to absorb and store more water and oxygen, further enhancing the water absorption capacity and water-oxygen barrier effect of the second barrier portion 262.

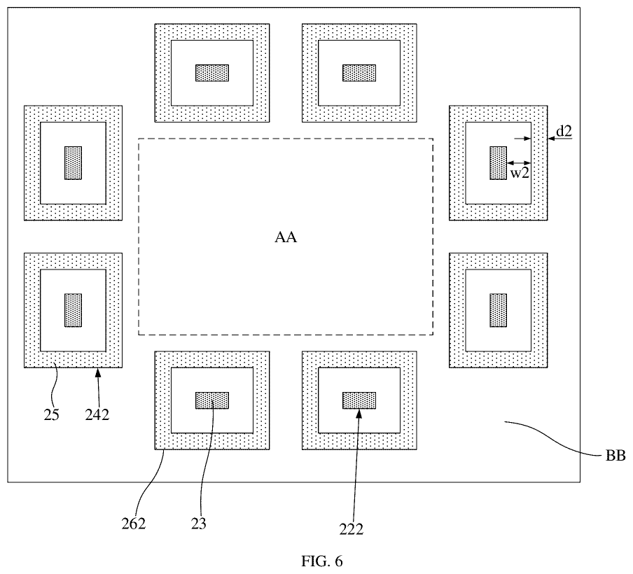

Referring to FIG. 6, FIG. 6 is a top structural schematic view of a cathode through hole and a second isolation groove according to other embodiments of the present disclosure. Unlike the embodiments as shown in FIG. 4, in the present embodiments, the second isolation groove 242 is provided in multiple numbers, with each isolation groove surrounding a corresponding cathode through hole 222. That is, each cathode through hole 222 is surrounded by a corresponding second isolation groove 242 on its outer side. This configuration may enhance the water-oxygen barrier effect of the second isolation grooves 242 on the cathode through holes 222, preventing water and oxygen from entering the cathode through holes 222 when water and oxygen are present in the ring-shaped region of the display region AA.

In the embodiments, the second preset distance w2 is defined as a distance between a side of the cathode through hole 222 close to the second isolation groove 242 surrounding its outer side and a side of the second isolation groove 242 close to the cathode through hole 222, on the surface of the second side 212 of the glass substrate 21 along the radial direction of the second isolation groove 242 or the radial direction of the cathode through hole 222. Specifically, the second isolation groove 242 and the corresponding cathode through hole 222 may be coaxially arranged. The second preset width d2 has the same definition as the second preset width d2 in the embodiments as shown in FIG. 4.

The numerical ranges of the second preset distance w2 and the second preset width d2 are the same as those in the embodiments as shown in FIG. 4. The second preset ratio between the second depth h2 and the reference thickness h0 of the glass substrate 21 is also the same as that in the embodiments as shown in FIG. 4, and specific details may be referred to the preceding description.

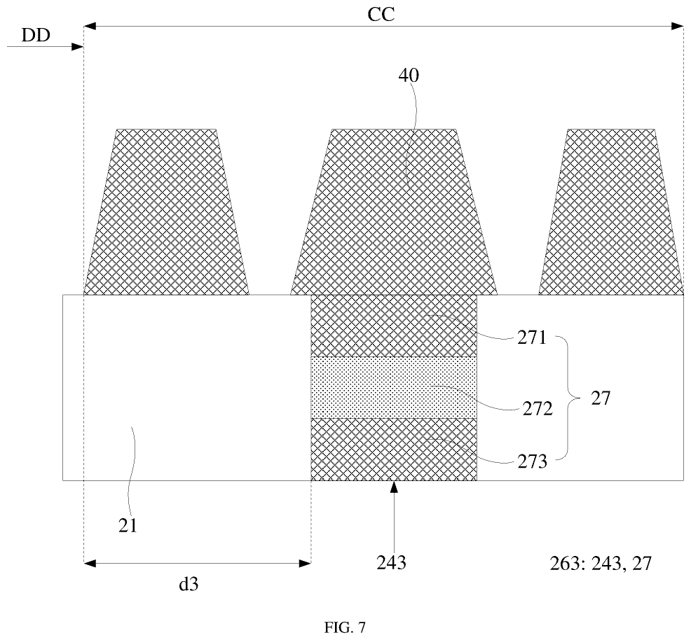

Referring to FIGS. 7 and 8, FIG. 7 is a longitudinal cross-sectional structural schematic view of a dam region according to some embodiments of the present disclosure, and FIG. 8 is a top structural schematic view of an isolation through hole according to some embodiments of the present disclosure. In the embodiments, an isolation through hole 243 is defined in an edge region of the glass substrate 21. The isolation through hole 243 is specifically disposed in the dam region CC. The isolation through hole 243 is filled with an absorption layer 27 to form a third barrier portion 263, which is configured to absorb and block water and oxygen, thereby isolating water and oxygen from the exterior. That is, the third barrier portion 263 serves as an additional water-oxygen barrier for the display region AA and the display edge region BB.

It can be understood that when the encapsulation between the glass substrate 21 and the drive substrate 10 fails, the third barrier portion 263 first acts as a first barrier to block external water and oxygen at this location, preventing them from entering the display edge region BB and the display region AA; the second barrier portion 262 acts as a second barrier to further block water and oxygen, preventing water and oxygen from entering the cathode through holes 222 and the display region AA; and the first barrier portion 261 acts as a third barrier, further blocking water and oxygen to prevent them from entering the anode through holes 221.

Furthermore, the absorption layer 27 within the isolation through hole 243 is connected to an isolation dam on the glass substrate 21, thereby increasing the extension path of water and oxygen on the isolation dam layer to some extent. That is, when the encapsulation between the drive substrate 10 and the glass substrate 21 fails, the absorption layer 27 can absorb water vapor from the drive substrate 10 and also transmit water vapor from the drive substrate 10 to the isolation dam layer. Since the dam region CC has multiple isolation dams, water vapor may be effectively stored, thereby further avoiding the risk of reduced lifespan of the display panel 100 due to encapsulation failure.

Specifically, an edge of the glass substrate 21 is further arranged with a sealing region DD, which is disposed on a side of the dam region CC away from the display region AA and surrounds the dam region CC; the isolation through hole 243 and the sealing region DD are separated by a third preset distance w3.

The third preset distance w3 is defined as a distance between a side of the isolation through hole 243 close to the sealing region DD and a side of the sealing region DD close to the isolation through hole 243, on the surface of the second side 212 of the glass substrate 21 along a radial direction of the dam region CC. In some embodiments, the diameter of the isolation through hole 243 is greater than the second preset width d2, and the third preset distance w3 is 50 to 100 μm, for example, 50 μm, 55 μm, 60 μm, 65 μm, 70 μm, 75 μm, 80 μm, 85 μm, 90 μm, 95 μm, or 100 μm, which may be determined based on factors such as the diameter of the isolation through hole 243 and the number of the isolation through holes 243.

Furthermore, along a depth direction of the isolation through hole 243, the absorption layer 27 includes a first moisture-absorbing layer 271, a second moisture-absorbing layer 272, and a third moisture-absorbing layer 273 that are stacked; the material of the first moisture-absorbing layer 271 and the third moisture-absorbing layer 273 is the same as the material of the isolation dam located in the dam region CC, and the material of the second moisture-absorbing layer 272 is the same as the material of the barrier layer 25. The material of the isolation dam is the same as that of a pixel definition layer, typically an organic resin material. For example, the material of the first moisture-absorbing layer 271 and the third moisture-absorbing layer 273 is an organic resin material, while the material of the second moisture-absorbing layer 272 is a porous foam material. The first moisture-absorbing layer 271 is connected to the isolation dam above it, thereby increasing the extension path of water and oxygen on the isolation dam layer to some extent. The third absorbent layer 273 can absorb water vapor that enters between the drive substrate 10 and the glass substrate 21 after encapsulation failure, while the intermediate second absorbent layer 272 can simultaneously absorb water and oxygen from both the upper and lower regions, thereby further enhancing the water-oxygen barrier effect of the third barrier portion 263.

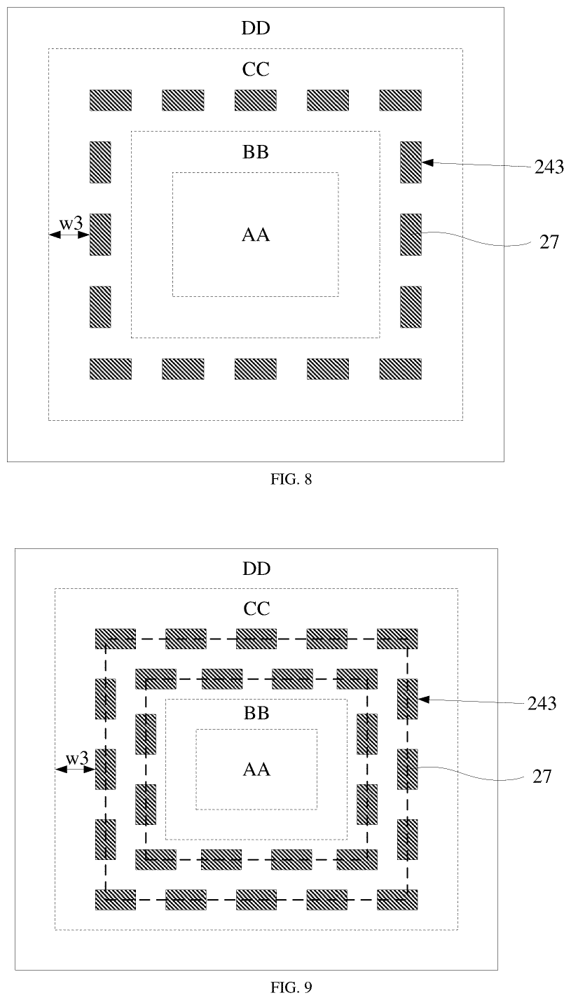

Referring to FIG. 9, FIG. 9 is a top structural schematic view of an isolation through hole according to other embodiments of the present disclosure. In the embodiments, the isolation through holes 243 are multiple, and the multiple isolation through holes 243 are arranged along a peripheral direction of the dam region CC; along the radial direction of the dam region CC, at least two rings of isolation through holes 243 are provided, and the isolation through holes 243 in one ring are misaligned from the isolation through holes 243 in another adjacent ring.

That is, the multiple isolation through holes 243 are arranged to form at least two rings, with each ring containing several isolation through holes 243, and the isolation through holes 243 in any one ring are misaligned from those in the adjacent ring, similar to bricks in a wall, where the bricks in each layer are misaligned from those in the adjacent layer. By setting at least two rings of isolation through holes 243, water and oxygen may be further blocked. In addition, the misalignment arrangement of the isolation through holes 243 in adjacent rings causes the direct invasion path of water and oxygen to become a curved path, thereby effectively extending the invasion path of water and oxygen and further enhancing the water-oxygen barrier effect of the third barrier portion 263.

Specifically, the isolation through hole 243 may be an elongated through hole or rectangular through hole to increase the capacity of the moisture-absorbing layer within the through holes, while also increasing the area of the isolation through holes 243 that blocks water and oxygen, thereby further enhancing the water-oxygen barrier effect. The length and width dimensions of the isolation through hole 243 in the direction parallel to the glass substrate 21 may be specifically set based on the number of isolation through holes 243, the area of the dam region CC, the spacing between adjacent isolation through holes 243, and the strength requirements of the glass substrate 21.

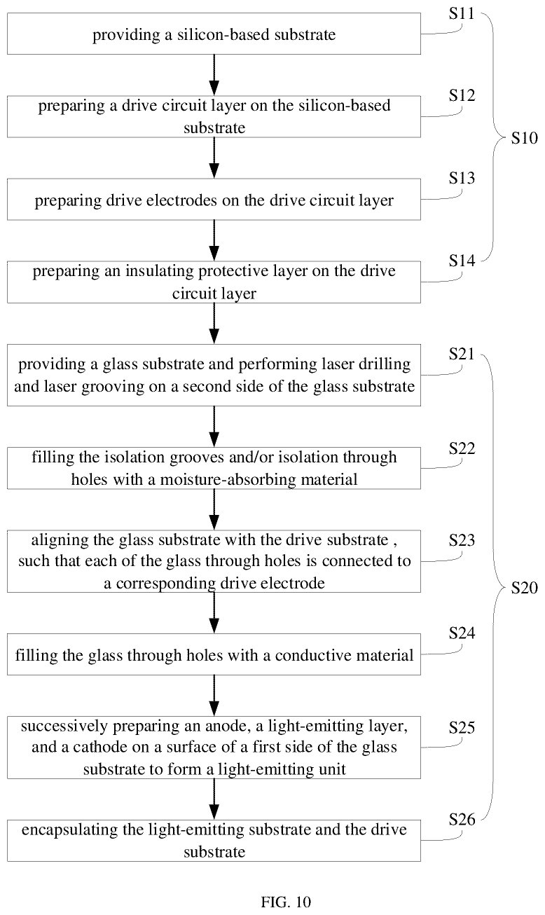

Referring to FIG. 10, FIG. 10 is a flowchart of a method for manufacturing a display panel according to some embodiments of the present disclosure. In the embodiments, a method for manufacturing a display panel is provided, which is configured to prepare the display panel 100 provided in the above-described embodiments. The manufacturing method specifically includes the following operations at blocks illustrated herein.

At block S10: preparing a drive substrate 10.

At block S20: preparing a light-emitting substrate 20 on the drive substrate 10.

The operation S10 specifically includes the following.

At block S11: providing a silicon-based substrate 11.

At block S12: preparing a drive circuit layer 12 on the silicon-based substrate 11.

At block S13: preparing drive electrodes 13 on the drive circuit layer 12.

At block S14: preparing an insulating protective layer 14 on the drive circuit layer 12.

Through the above operations, the drive substrate 10 is prepared and formed. The specific structure and function of the drive substrate 10 are the same or similar to those of the drive substrate 10 provided in the above embodiments, and can achieve the same technical effects. For details, reference may be made to the relevant descriptions above.

The operation S20 specifically includes the following.

At block S21: providing a glass substrate 21 and performing laser drilling and laser grooving on a second side 212 of the glass substrate 21.

At block S22: filling the isolation grooves and/or isolation through holes 243 with a moisture-absorbing material.

At block S23: aligning the glass substrate 21 with the drive substrate 10, such that each of the glass through holes 22 is connected to a corresponding drive electrode 13.

At block S24: filling the glass through holes 22 with a conductive material.

At block S25: successively preparing an anode 31, a light-emitting layer 32, and a cathode 33 on a surface of a first side 211 of the glass substrate 21 to form a light-emitting unit 30.

At block S26: encapsulating the light-emitting substrate 20 and the drive substrate 10.

The display panel 100 prepared according to the above embodiments has the same or similar specific structure and functions as the display panel 100 provided in the above embodiments, and can achieve the same technical effects. For details, reference may be made to the relevant descriptions above.

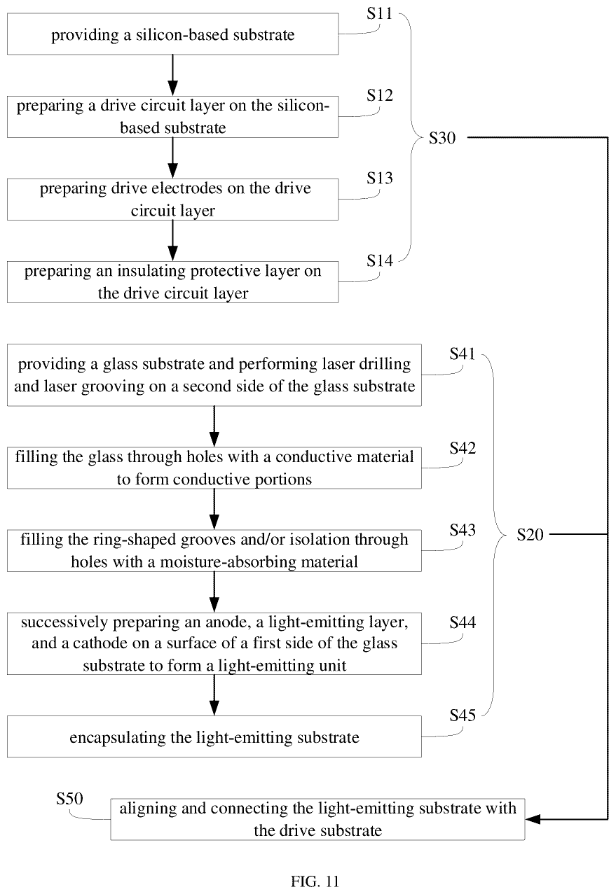

Referring to FIG. 11, FIG. 11 is a flowchart of a method for manufacturing a display panel according to other embodiments of the present disclosure. In the embodiments, another method for manufacturing a display panel is provided, which is configured to prepare the display panel 100 provided in the above embodiments. The manufacturing method specifically includes the following operations at blocks illustrated herein.

At block S30: preparing a drive substrate 10.

At block S40: preparing a light-emitting substrate 20.

At block S50: aligning and connecting the light-emitting substrate 20 with the drive substrate 10.

The specific process of the operation S30 is the same as that of the operation S10 in the previous embodiment, including S11 to S14.

The specific process of the operation S40 includes the following.

At block S41: providing a glass substrate 21 and performing laser drilling and laser grooving on a second side 212 of the glass substrate 21.

At block S42: filling the glass through holes 22 with a conductive material to form conductive portions 23.

At block S43: filling the ring-shaped grooves 24 and/or isolation through holes 243 with a moisture-absorbing material.

At block S44: successively preparing an anode 31, a light-emitting layer 32, and a cathode 33 on a surface of a first side 211 of the glass substrate 21 to form a light-emitting unit 30.

At block S45: encapsulating the light-emitting substrate 20.

In the embodiments, the operations of S30 and S40 are not performed in a specific order, and the drive substrate 10 and the light-emitting substrate 20 may be prepared separately and independently, thereby improving production efficiency. The operation S43 may be performed after S45 and before S50, and the specific order may be determined based on actual preparation requirements.

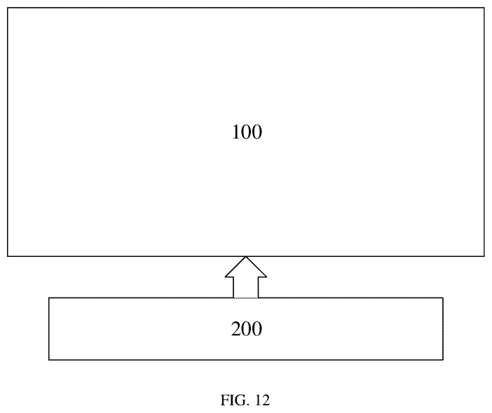

Referring to FIG. 12, FIG. 12 is a structural schematic view of a display device according to some embodiments of the present disclosure. In the embodiments, a display device is provided, which includes a display panel 100 and a control circuit board 200. The display panel 100 is the same as the display panel 100 provided in the above embodiments. The control circuit board 200 is electrically connected to the display panel 100, specifically to the drive substrate 10, and is configured to control the display panel 100 to display corresponding images according to corresponding control modes.

The display device may effectively enhance the signal reliability of the signal channel between the display panel 100 and the drive substrate 10, effectively preventing water and oxygen from invading the signal channel and entering the light-emitting substrate 20 along the signal channel, thereby ensuring the service life of the display panel 100.

The beneficial effects of the present disclosure: Different from the related art, the present disclosure provides a display panel and a display device. The display panel includes a drive substrate and a light-emitting substrate. By configuring the light-emitting substrate to include a glass substrate and light-emitting units disposed on the glass substrate, and by disposing the glass substrate on the drive substrate, the glass substrate is further disposed between the light-emitting units and the drive substrate. The light-emitting units are fabricated on the glass substrate, and the glass substrate protects the drive circuit layer on the drive substrate, thereby avoiding the impact and damage caused by directly forming the light-emitting units on the drive substrate, and improving the product yield rate. By defining glass through holes on the glass substrate and providing conductive portions within the glass through holes, the light-emitting units can be connected to the drive substrate via the conductive portions to display corresponding images. Furthermore, by defining a ring-shaped groove around the glass through holes on a second side of the glass substrate close to the drive substrate and arranging a barrier layer within the ring-shaped groove, water vapor and oxygen are absorbed and prevented from entering the glass through-holes. This may prevent water vapor and oxygen from spreading into the glass through holes and along the glass through holes into the light-emitting units after the encapsulation between the glass substrate and the drive substrate fails, thereby enhancing the long-term reliability of the through holes.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A display panel, comprising:
a drive substrate, comprising a drive circuit layer and a plurality of drive electrodes that are electrically connected to the drive circuit layer; and
a light-emitting substrate, comprising:
a glass substrate, disposed on the drive substrate; wherein the glass substrate defines a plurality of glass through holes on a second side of the glass substrate corresponding to and facing the plurality of drive electrodes; the second side is opposite to the first side; each of the plurality of glass through holes is filled with a conductive portion, and the conductive portion is electrically connected to a corresponding drive electrode; and
a plurality of light-emitting units, arranged in an array on a first side of the glass substrate; wherein an anode of each of the plurality of light-emitting units is electrically connected to a corresponding conductive portion;
wherein the second side of the glass substrate close to the drive substrate defines a ring-shaped groove that surrounds the plurality of glass through holes; a barrier layer is disposed within the ring-shaped groove to absorb water and oxygen and prevent the water and oxygen from entering the plurality of glass through holes.

2. The display panel according to claim 1, wherein the plurality of glass through holes comprise a plurality of anode through holes disposed in a display region; the ring-shaped groove comprises a plurality of first isolation grooves each arranged around a corresponding anode through hole, and each first isolation groove is filled with the barrier layer to form a first barrier portion.

3. The display panel according to claim 2, wherein on a surface of the glass substrate close to the drive substrate, each first isolation groove is spaced apart from a corresponding anode through hole by a first preset distance, and the first isolation groove has a first preset width; the first preset distance is less than half a distance between adjacent two of the plurality of anode through holes;
in a thickness direction of the glass substrate, a first depth of each first isolation groove has a first preset ratio with respect to a reference thickness of the glass substrate; the first preset ratio is in a range from 1:3 to 1:2.

4. The display panel according to claim 3, wherein the plurality of glass through holes comprise a plurality of cathode through holes disposed in a display edge region; the display edge region is disposed on an outer side of the display region and surrounds the display region;
the ring-shaped groove comprises a second isolation groove disposed around the plurality of cathode through holes, and the second isolation groove is filled with the barrier layer to form a second barrier portion.

5. The display panel according to claim 4, wherein on the surface of the glass substrate close to the drive substrate, the second isolation groove is spaced apart from each of the plurality of cathode through holes by a second preset distance, and the second isolation groove has a second preset width; the second preset distance is greater than the first preset distance, and the second preset width is greater than the first preset width;
in the thickness direction of the glass substrate, a second depth of the second isolation groove has a second preset ratio with respect to the reference thickness of the glass substrate; the second preset ratio is in a range from 2:5 to 3:5.

6. The display panel according to claim 5, wherein an isolation through hole is defined on the glass substrate, and the isolation through hole is disposed in a dam region; the dam region is disposed on a side of the display edge region away from the display region and surrounds the display edge region;
the isolation through hole is filled with an absorption layer to form a third barrier portion that is configured to absorb and block water and oxygen.

7. The display panel according to claim 6, wherein an edge of the glass substrate is arranged with a sealing region that is disposed on a side of the dam region away from the display region and surrounds the dam region; the isolation through hole and the sealing region are separated by a third preset distance.

8. The display panel according to claim 7, wherein the absorption layer is connected to an isolation dam disposed in the dam region and on the glass substrate;
along a depth direction of the isolation through hole, the absorption layer comprises a first moisture-absorbing layer, a second moisture-absorbing layer, and a third moisture-absorbing layer that are stacked; a material of the first moisture-absorbing layer and a material of the third moisture-absorbing layer are same as a material of the isolation dam disposed in the dam region, and a material of the second moisture-absorbing layer is same as a material of the barrier layer.

9. The display panel according to claim 7, wherein a diameter of the isolation through hole is greater than the second preset width, and the third preset distance is in a range from 50 to 100 μm,

10. The display panel according to claim 6, wherein the isolation through hole comprises a plurality of isolation through holes, and the plurality of isolation through holes are arranged along a peripheral direction of the dam region; along a radial direction of the dam region, the plurality of isolation through holes are arranged in at least two rings, and the isolation through holes in one of the at least two rings are misaligned from the isolation through holes in another adjacent one of the at least two rings.

11. The display panel according to claim 8, wherein each of the plurality of isolation through holes is an elongated through hole or a rectangular through hole.

12. The display panel according to claim 3, wherein the plurality of glass through holes comprise a plurality of cathode through holes disposed in a display edge region; the display edge region is disposed on an outer side of the display region and surrounds the display region;
the ring-shaped groove comprises a plurality of second isolation grooves each disposed around a corresponding cathode through hole, and each second isolation groove is filled with the barrier layer to form a second barrier portion.

13. The display panel according to claim 12, wherein on the surface of the glass substrate close to the drive substrate, each second isolation groove is spaced apart from a corresponding cathode through hole by a second preset distance, and the second isolation groove has a second preset width; the second preset distance is greater than the first preset distance, and the second preset width is greater than the first preset width;
in the thickness direction of the glass substrate, a second depth of the second isolation groove has a second preset ratio with respect to the reference thickness of the glass substrate; the second preset ratio is in a range from 2:5 to 3:5.

14. The display panel according to claim 1, wherein a material of the barrier layer is at least one of porous foam and an organic water-absorbing material.

15. A method for manufacturing a display panel, comprising:
preparing a drive substrate, comprising:
preparing a drive circuit layer; and
preparing a plurality of drive electrodes that are electrically connected to the drive circuit layer;
preparing a light-emitting substrate on the drive substrate, comprising:
providing a glass substrate disposed on the drive substrate, and performing laser drilling on a second side of the glass substrate to define a plurality of glass through holes corresponding to and facing the plurality of drive electrodes;
filling each glass through hole with a conductive material to form a conductive portion;
wherein the conductive portion is electrically connected to a corresponding drive electrode; and
preparing a plurality of light-emitting units that are arranged in an array on a first side of the glass substrate; wherein the second side is opposite to the first side; an anode of each of the plurality of light-emitting units is electrically connected to a corresponding conductive portion; and
aligning and connecting the light-emitting substrate with the drive substrate;
wherein the second side of the glass substrate close to the drive substrate defines a ring-shaped groove that surrounds the plurality of glass through holes; a barrier layer is disposed within the ring-shaped groove to absorb water and oxygen and prevent the water and oxygen from entering the plurality of glass through holes.

16. A display device, comprising:
a display panel; and
a control circuit board, electrically connected to the display panel and configured to control the display panel;
wherein the display panel comprises:
a drive substrate, comprising a drive circuit layer and a plurality of drive electrodes that are electrically connected to the drive circuit layer; and
a light-emitting substrate, comprising:
a glass substrate, disposed on the drive substrate; wherein the glass substrate defines a plurality of glass through holes on a second side of the glass substrate corresponding to and facing the plurality of drive electrodes; the second side is opposite to the first side; each of the plurality of glass through holes is filled with a conductive portion, and the conductive portion is electrically connected to a corresponding drive electrode; and
a plurality of light-emitting units, arranged in an array on a first side of the glass substrate; wherein an anode of each of the plurality of light-emitting units is electrically connected to a corresponding conductive portion;
wherein the second side of the glass substrate close to the drive substrate defines a ring-shaped groove that surrounds the plurality of glass through holes; a barrier layer is disposed within the ring-shaped groove to absorb water and oxygen and prevent the water and oxygen from entering the plurality of glass through holes.

17. The display device according to claim 16, wherein the plurality of glass through holes comprise a plurality of anode through holes disposed in a display region; the ring-shaped groove comprises a plurality of first isolation grooves each arranged around a corresponding anode through hole, and each first isolation groove is filled with the barrier layer to form a first barrier portion.

18. The display device according to claim 17, wherein on a surface of the glass substrate close to the drive substrate, each first isolation groove is spaced apart from a corresponding anode through hole by a first preset distance, and the first isolation groove has a first preset width; the first preset distance is less than half a distance between adjacent two of the plurality of anode through holes;
in a thickness direction of the glass substrate, a first depth of each first isolation groove has a first preset ratio with respect to a reference thickness of the glass substrate; the first preset ratio is in a range from 1:3 to 1:2.

19. The display device according to claim 18, wherein the plurality of glass through holes comprise a plurality of cathode through holes disposed in a display edge region; the display edge region is disposed on an outer side of the display region and surrounds the display region;
the ring-shaped groove comprises a second isolation groove disposed around the plurality of cathode through holes, and the second isolation groove is filled with the barrier layer to form a second barrier portion.

20. The display device according to claim 19, wherein on the surface of the glass substrate close to the drive substrate, the second isolation groove is spaced apart from each of the plurality of cathode through holes by a second preset distance, and the second isolation groove has a second preset width; the second preset distance is greater than the first preset distance, and the second preset width is greater than the first preset width;
in the thickness direction of the glass substrate, a second depth of the second isolation groove has a second preset ratio with respect to the reference thickness of the glass substrate; the second preset ratio is in a range from 2:5 to 3:5.
